(19) United States
(12) Patent Application Publication
(10) Pub. No.: US 2005/0247973 A1
(43) Pub. Date: Nov. 10, 2005

(54) Nonvolatile memory device and method for fabricating the same

(75) Inventor: Sang Bum Lee, Bupyeong-gu (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/121,866

(22) Filed: May 3, 2005

(30) Foreign Application Priority Data
May 6, 2004 (KR) 10-2004-0031865

(51) Int. Cl. H01L 29/792

(52) U.S. Cl. 257/325

(57) ABSTRACT

A nonvolatile memory device and a method for fabricating the same is disclosed, in which a corner of a floating gate is rounded to reduce, minimize or prevent discharge of programmed electrons, and an overlap between the floating gate and a control gate increases to improve a coupling ratio and enable nonvolatile memory device operations at a low voltage. The nonvolatile memory device includes a device isolation layer in a field region on a semiconductor substrate, the device isolation having a trench; a tunnel oxide layer; a floating gate comprising a polysilicon pattern in an active region of the semiconductor substrate and a polysilicon spacer at the side of the polysilicon pattern and the inner sidewall of the trench; a gate dielectric layer on the floating gate; and a control gate on the gate dielectric layer overlapping with the floating gate.

### CROSS-REFERENCE TO RELATED APPLICATIONS

This application claims the benefit of Korean Application No. P2004-31865, filed on May 6, 2004, which is hereby incorporated by reference as if fully set forth herein.

### BACKGROUND OF THE INVENTION

1. Field of the Invention

The present invention relates to a nonvolatile memory device and a method for fabricating the same, and more particularly, to a floating gate of an ETOX nonvolatile memory device and a method for fabricating the same, adapted to improve the reliability of the device.

2. Discussion of the Related Art

Generally, nonvolatile memory devices are advantageous in that data is not lost when a power supply is stopped. In this respect, nonvolatile memory devices are widely used for data storage of a PC BIOS, a set-top box, a printer or a network server. Recently, nonvolatile memory devices are also used for a digital camera and a mobile phone.

Among nonvolatile memory devices, an EEPROM (Electrically Erasable Programmable Read-Only Memory) type nonvolatile memory device may completely erase data from memory cells, or may erase data from memory cells by each unit sector. In this EEPROM type nonvolatile memory device, in a programming mode, channel hot electrons are generated at the side of the drain and stored in a floating gate, whereby a threshold voltage of a cell transistor increases. In an erasing mode of the EEPROM type nonvolatile memory device, a relatively high voltage is generated between the floating gate and source/substrate, and the channel hot electron stored in the floating gate is discharged, thereby lowering the threshold voltage of the cell transistor.

The EEPROM type nonvolatile memory device may have an ETOX cell or a split gate type cell. The ETOX cell is formed in a simple stack structure. In case of the split gate type cell, two transistors are formed in each cell. Specifically, in case of the ETOX cell, one memory cell has the stack structure of a floating gate and a control gate, wherein the floating gate stores charges therein, and the control gate receives a driving power. Meanwhile, the split gate type cell includes two transistors; that is, a selection transistor for selecting the cell, and a memory transistor for storing the data. The memory transistor includes a floating gate, a control gate electrode, and a gate interlayer dielectric, wherein the floating gate stores charges therein, the control gate electrode controls the memory transistor, and the gate interlayer dielectric is interposed between the floating gate and the control gate electrode.

FIG. 1 is a plane view of an ETOX nonvolatile memory cell layout according to the related art. FIG. 2 is a cross sectional view along I-I′ of FIG. 1. FIG. 3A to FIG. 3D are cross sectional views of the process for fabricating an ETOX nonvolatile memory cell according to the related art.

As shown in FIG. 1 and FIG. 2, a semiconductor substrate 11 contains a field region and an active region. A device isolation layer 12 is formed in the field region of the semiconductor substrate 11. At this time, the device isolation layer 12 is formed by LOCOS (Local Oxidation of Silicon) or STI (Shallow Trench Isolation).

Then, a tunnel oxide layer 14 and a floating gate 15 are formed on a predetermined portion of the active region of the semiconductor substrate 11, and an ONO layer 16 is formed on the floating gate 15. Also, a control gate 17 is formed on the ONO layer 16 that overlaps with the floating gate 15. The floating gate 15 provides a means for storing electric charges, and the control gate 17 provides a means for maintaining a voltage in the floating gate 15 (and/or reading and/or programming the nonvolatile memory cell).

Then, source and drain regions 18 and 19 are formed at both sides of the floating gate 15 and the control gate 17 in the active region of the semiconductor substrate 11, and a drain contact 20 is formed in the drain region 19.

In the programming mode of the ETOX nonvolatile memory cell, channel hot electrons are generated in a channel region at one side of the drain region 19, and the electrons are stored in the floating gate 15, whereby a threshold voltage of a cell transistor increases. In the meantime, in the erasing mode, a relatively high voltage is generated between the source region 18 and the floating gate 15, whereby the electrons stored in the floating gate 15 are discharged, thereby lowering the threshold voltage.

A method for fabricating the ETOX nonvolatile memory device according to the related art will be described as follows.

As shown in FIG. 3A, a buffer oxide layer 13a and a buffer nitride layer 13b are formed on the semiconductor substrate 11, and then are selectively removed by photolithography, thereby exposing the semiconductor substrate 11 corresponding to the field region.

Subsequently, the semiconductor substrate 11 is etched to a predetermined depth using the buffer oxide layer 13a and the buffer nitride layer 13b as a mask, thereby forming a trench. Then, an oxide layer is formed in the trench, thereby forming the device isolation layer 12 (e.g., an STI structure).

Although not shown, impurity ions are implanted to the active region of the semiconductor substrate 11 having no device isolation layer 12, thereby forming a well region.

As shown in FIG. 3B, after removing the buffer oxide layer 13a and the buffer nitride layer 13b, a first polysilicon layer 15a is formed on an entire surface of the semiconductor substrate 11 after forming the tunnel oxide layer 14 on the semiconductor substrate 11.

Referring to FIG. 3C, the tunnel oxide layer 14 and the first polysilicon layer 15a are selectively removed by photolithography, whereby the tunnel oxide layer 14 and the first polysilicon layer 15a remain on the active region of the semiconductor substrate 11 and the device isolation layer 12 adjacent to the active region, thereby forming the floating gate 15.

As shown in FIG. 3D, the ONO layer 16 and a second polysilicon layer are sequentially formed on the entire surface of the semiconductor substrate 11 including the floating gate 15, and then are selectively removed by photolithography, thereby forming the control gate 17. At this time, the ONO layer 16 includes an oxide layer, a nitride layer and another oxide layer in a stacked structure.

Although not shown, impurity ions are implanted to the active region of the semiconductor substrate 11 using the control gate as a mask, thereby forming the source and drain regions 18 and 19. Then, an insulating interlayer is formed on the entire surface of the semiconductor substrate 11, and the drain contact 20 is formed in the insulating interlayer (not shown), wherein the drain contact 20 connects the drain region 19 with the bit line BL.

On programming the ETOX cell type nonvolatile memory device according to the related art, a programming voltage is applied from a word line WL to the control gate 17, and from the bit line BL to the drain region 19. Accordingly, electrons from the drain region 19 tunnel through the tunnel oxide layer 14 by hot carrier injection, whereby the electrons tunnel to (or are injected into) the floating gate 15, thereby programming the memory cell.

On erasing the ETOX cell type nonvolatile memory device according to the related art, an erasing voltage is applied to the source region 18 by a source line SL. Then, electrons stored in or on the floating gate 15 are discharged through the tunnel oxide layer 14, lowering the threshold voltage of the cell transistor and erasing the memory cell.

However, the ETOX nonvolatile memory cell according to the related art has the following disadvantages.

As shown in FIG. 2 and ‘A’ of FIG. 3D, the corner of the floating gate can be sharply patterned, whereby an electric field may concentrate at the corners of the floating gate. Accordingly, on programming the ETOX cell type nonvolatile memory device, electrons may be discharged so that the data is lost, thereby deteriorating the reliability of the nonvolatile memory device.

### SUMMARY OF THE INVENTION

Accordingly, the present invention is directed to a nonvolatile memory device and a method for fabricating the same that substantially obviates one or more problems due to limitations and disadvantages of the related art.

An object of the present invention is to provide a nonvolatile memory device and a method for fabricating the same, in which a rounded corner of a floating gate reduces, minimizes or prevents discharge of programmed electrons, and an overlap between the floating gate and a control gate increases to improve a coupling ratio and enable nonvolatile memory device operations at a low voltage.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a nonvolatile memory device includes a device isolation layer in a field region on a semiconductor substrate, the device isolation having a trench therein; a tunnel oxide layer; a floating gate comprising a polysilicon pattern in the active region of the semiconductor substrate and a polysilicon spacer at a side of the first polysilicon pattern and the inner sidewall of the trench; a gate dielectric layer on the floating gate; and a control gate on the gate dielectric layer overlapping with the floating gate.

In another aspect, a method for fabricating a nonvolatile memory device includes the steps of forming a device isolation layer in a field region of a semiconductor substrate; forming a tunnel oxide layer and a first polysilicon layer on the semiconductor substrate; forming a polysilicon pattern by selectively removing portions of the tunnel oxide layer and the first polysilicon layer; forming a trench in the device isolation layer; forming a polysilicon spacer at the side of the polysilicon pattern and the inner sidewall of the trench; and forming a gate dielectric layer and a control gate on the polysilicon pattern and the polysilicon spacer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle(s) of the invention. In the drawings:

FIG. 1 is a plane view of an ETOX nonvolatile memory cell according to the related art;

FIG. 2 is a cross sectional view along I-I′ of FIG. 1;

FIG. 3A to FIG. 3D are cross sectional views of the process for fabricating an ETOX nonvolatile memory cell according to the related art;

FIG. 4 is a cross sectional view of an ETOX nonvolatile memory cell according to the present invention; and

FIG. 5A to FIG. 5E are cross sectional views of the process for fabricating an ETOX nonvolatile memory cell according to the present invention.

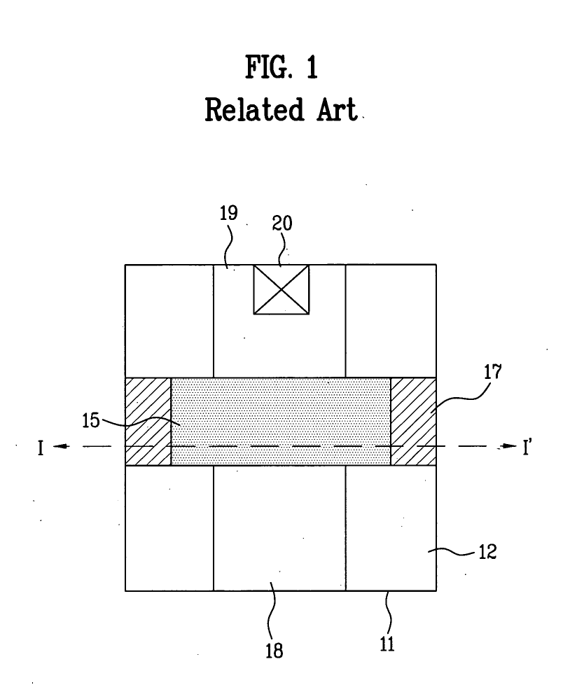

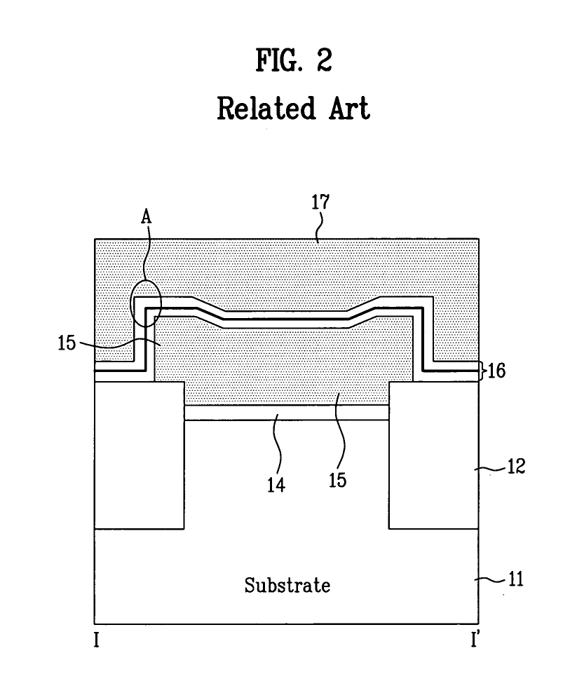

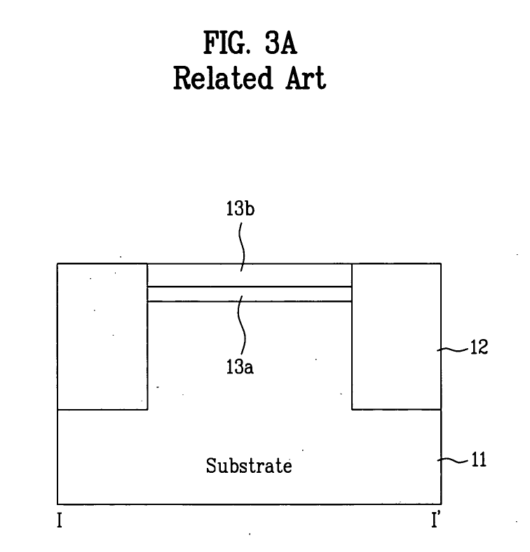

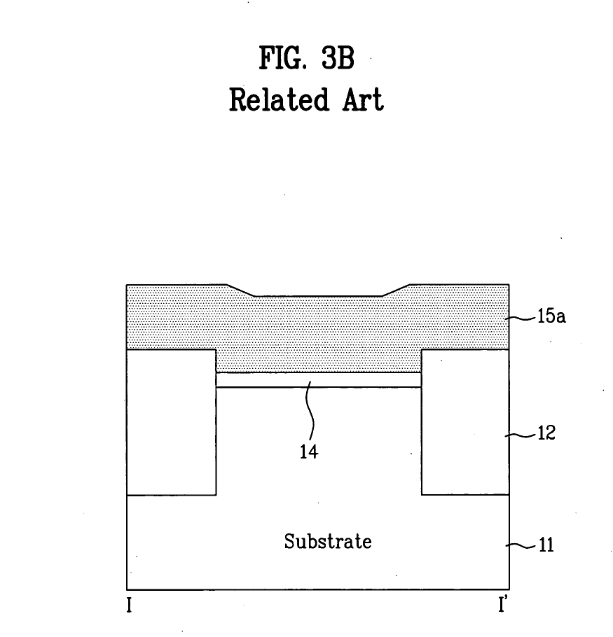

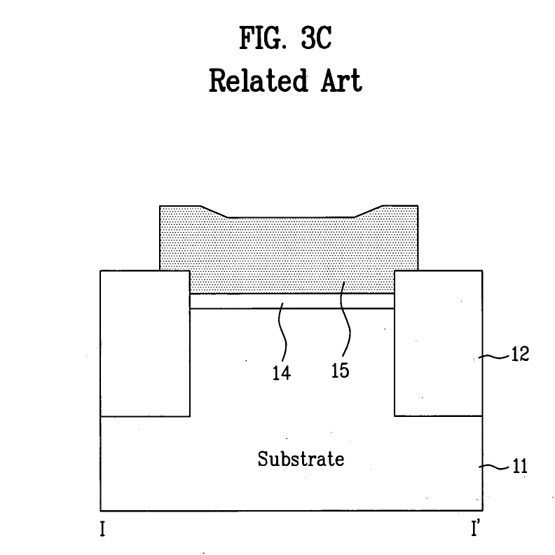

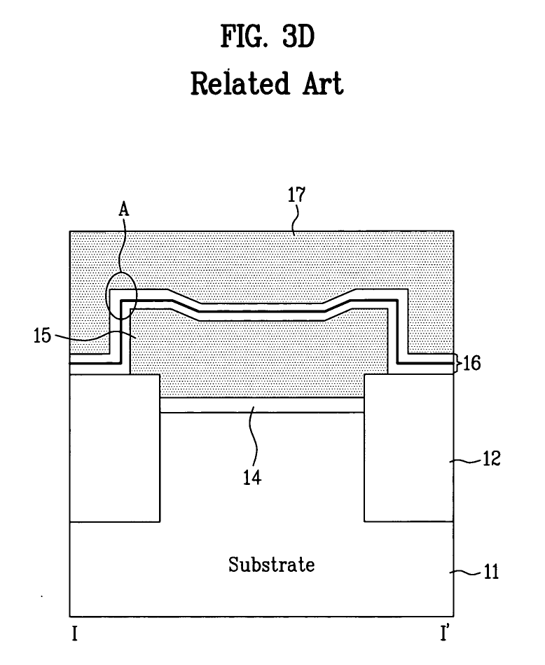

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a nonvolatile memory device and a method for fabricating the same according to the present invention will be described with reference to the accompanying drawings.

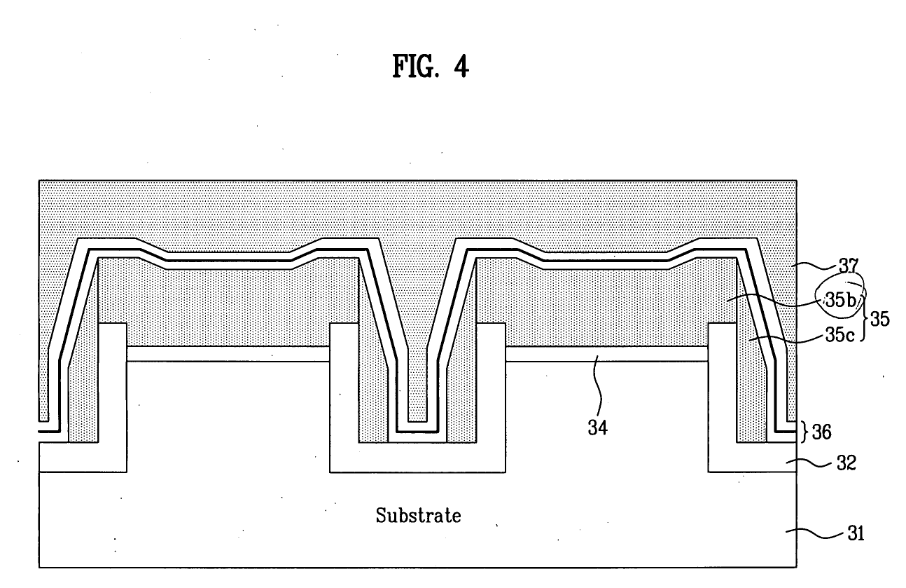

FIG. 4 is a cross sectional view of an ETOX nonvolatile memory cell according to the present invention.

As shown in FIG. 4, an ETOX nonvolatile memory device according to the present invention includes a semiconductor substrate 31, wherein the semiconductor substrate contains a field region and an active region. Then, a device isolation layer 32 is formed in the field region of the semiconductor substrate 31. The device isolation layer 32 comprises an STI (shallow trench isolation) structure, and the device isolation layer 32 has a recess or trench in the center thereof. Generally, the STI structure comprises an oxide, but it may further comprise a nitride liner and/or an oxide buffer layer thereunder. Alternatively, the device isolation layer 32 may comprise a LOCOS (local oxidation of silicon) structure. In either case, the terms “recess” and “trench” are used interchangeably herein, and use of one such term generally encompasses the other.

After that, a tunnel oxide layer 34 and a polysilicon pattern 35b are formed on a predetermined portion of active regions of the semiconductor substrate 31. Then, a polysilicon spacer 35c is formed at the side of the first polysilicon pattern 35b and at the side of the recess in the device isolation layer 32. At this time, the polysilicon pattern and polysilicon spacer 35b and 35c are electrically connected to each other, thereby forming a floating gate 35.

Then, a gate dielectric (e.g., an ONO) layer 36 is formed on the semiconductor substrate 31 and the floating gate 35, and a control gate 37 is formed on the gate dielectric layer 36, wherein the control gate 37 overlaps with the floating gate 35. Alternatively, the gate dielectric layer 36 may consist essentially of a single oxide layer, which may be formed by CVD of TEOS or a silane/oxygen mixture. At this time, the floating gate 35 functions to store electric charges (and thus comprises as a means for storing electric charges), and the control gate 37 functions to control operations (e.g., as a means for maintaining a voltage) in the floating gate 35.

Although not shown, source and drain regions are formed at sides of the floating gate 35 and the control gate 37 in the active region of the semiconductor substrate 31, and a bit line BL may be connected with the drain region.

As described above, the floating gate 35 of the ETOX nonvolatile memory cell according to the present invention comprises the polysilicon pattern 35b and the polysilicon spacer 35c, wherein the polysilicon spacer 35c is at the side of the polysilicon pattern 35b. Accordingly, the sharp corner(s) of the polysilicon pattern 35b is/are covered with the polysilicon spacer 35c, so that the floating gate 35 has no sharp corner.

Also, the floating gate 35 is formed at the side of the device isolation layer 32 as well as on the tunneling oxide layer 34, whereby it is possible to increase the overlapped portion between the floating gate 35 and the control gate 37, thereby increasing a coupling ratio.

A method for fabricating the nonvolatile memory device according to the present invention will be described as follows.

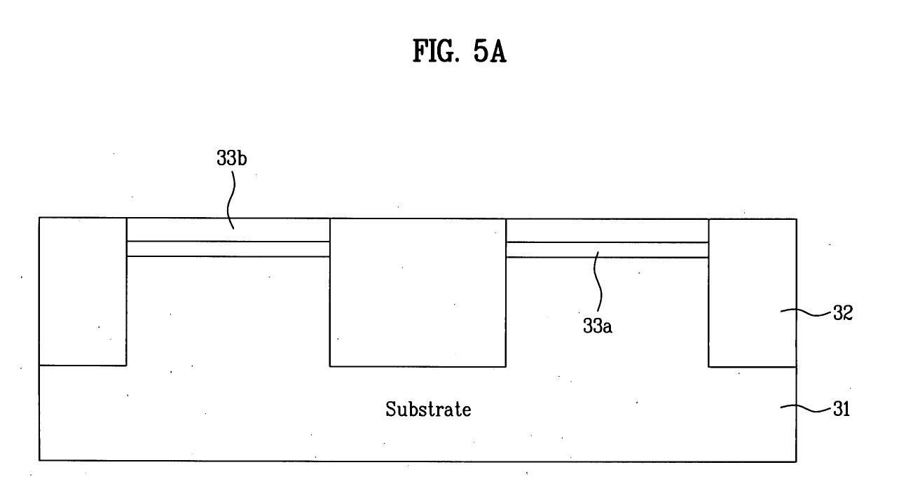

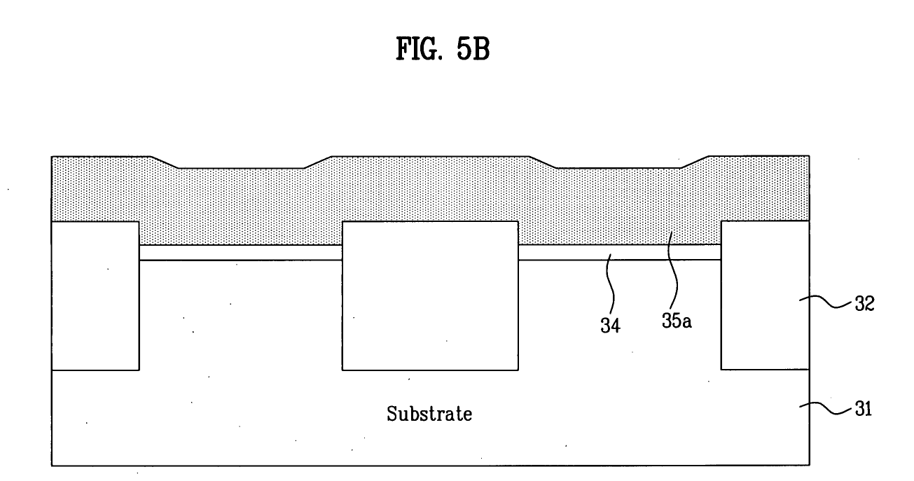

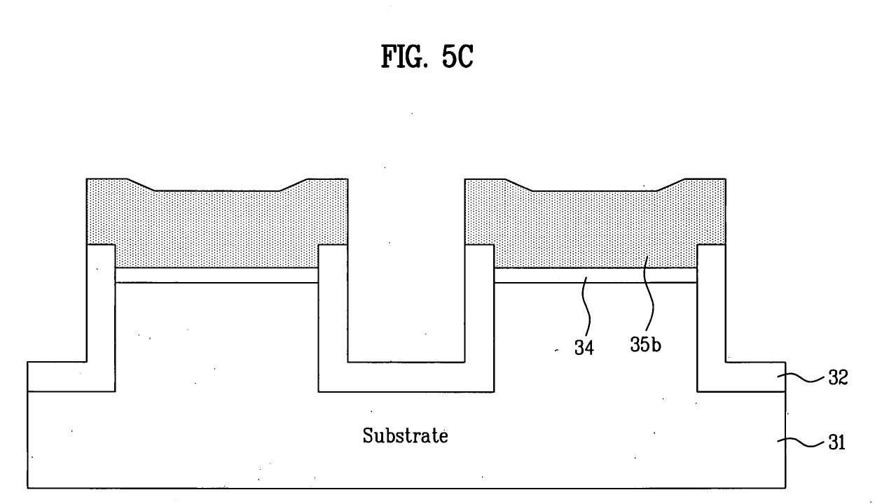

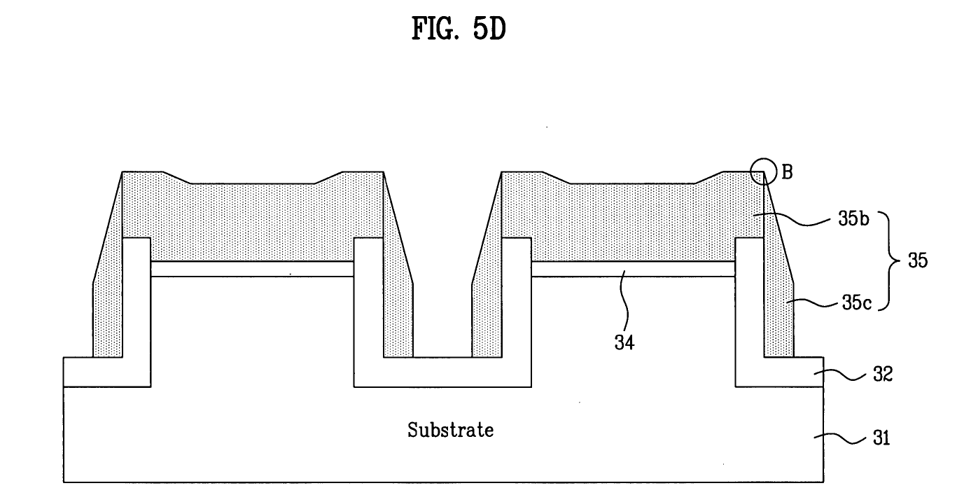

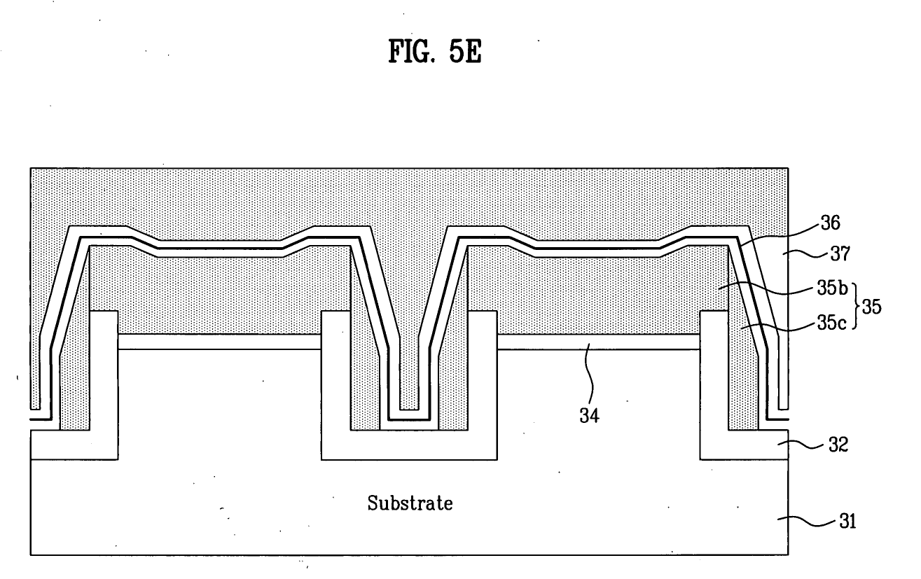

FIG. 5A to FIG. 5E are cross sectional views of the process for fabricating the ETOX nonvolatile memory cell according to the present invention.

As shown in FIG. 5A, a buffer oxide layer 33a and a buffer nitride layer 33b are formed on the semiconductor substrate 31, and then are selectively removed by photolithography, thereby exposing the field regions of the semiconductor substrate 31.

After that, the semiconductor substrate 31 is etched to a predetermined depth using the patterned buffer oxide layer 33a and buffer nitride layer 33b as a mask, thereby forming a trench. Then, an oxide layer is deposited or otherwise formed in the trench, thereby forming the device isolation layer 32 as an STI structure or LOCOS structure. Also, impurity ions are implanted into the active region of the semiconductor substrate 31, thereby forming a well region (not shown).

As shown in FIG. 5B, after removing the buffer oxide layer 33a and the buffer nitride layer 33b, the tunnel oxide layer 34 and a first polysilicon layer 35a are sequentially stacked (e.g., by blanket deposition) on an entire surface of the semiconductor substrate 31.

Referring to FIG. 5C, the tunnel oxide layer 34 and the first polysilicon layer 35a are etched to remove portions thereof on the semiconductor substrate 31 in the active region and on part of the device isolation layer 32 adjacent to the active region, thereby forming the polysilicon pattern 35b. At this time, the device isolation layer 32 is removed to a predetermined depth by over-etch (e.g., by over-etching the tunnel oxide layer 34), whereby the trench is formed in the device isolation layer 32. Generally, the trench has a width substantially equal to or less than a width of the device isolation layer 32 minus two times the width of the portion of the patterned first polysilicon layer that overlaps with the device isolation layer.

As shown in FIG. 5D, a second polysilicon layer is formed on the entire surface of the semiconductor substrate 31, and then is etched back by an anisotropic etch process, whereby the polysilicon spacer 35c is formed at the side of the polysilicon pattern 35b and the inner sidewall of the trench in the device isolation layer 32. That is, the polysilicon pattern 35b is electrically connected with the polysilicon spacer 35c, thereby forming the floating gate 35. Accordingly, the floating gate 35 has a rounded shape by virtue of the polysilicon spacer 35c, as shown in ‘B’ of FIG. 5D, thereby reducing, minimizing or preventing the loss of data generated by concentration of electric field at such corners.

As shown in FIG. 5E, the gate dielectric layer 36 (e.g., an ONO layer comprising an oxide layer-nitride layer-oxide layer stack) and a third polysilicon layer are sequentially formed on the entire surface of the semiconductor substrate 31 and the floating gate 35 (e.g., by blanket deposition), and then are selectively removed by photolithography, thereby forming the control gate 37.

Although not shown, impurity ions are implanted to the active region of the semiconductor substrate 31 in state of using the control gate 37 as a mask, thereby forming the source and drain regions at both sides of the control gate 37 in the active region of the semiconductor substrate 31. Then, an insulating layer is formed on the entire surface of the semiconductor substrate 31, and then contacts are formed to the source, drain, and control gate as described herein (e.g., the drain contact is formed by connecting the drain region with the bit line BL through the insulating layer), thereby completing the nonvolatile memory device.

As mentioned above, the nonvolatile memory device and the method for fabricating the same according to the present invention have the following advantages.

First, upper corners of the floating gate have a round shape, thereby reducing or preventing the concentration of electric fields at such corners. Accordingly, loss of data at such corners of the floating gate may be reduced or prevented, thereby improving the reliability of the nonvolatile memory device.

Also, the surface area of the floating gate increases, so that the overlap between the floating gate and the control gate increases, thereby improving the coupling ratio. Accordingly, it is possible to decrease the power consumption since the flash memory device may operate at a relatively low voltage.

Furthermore, because the nonvolatile memory device may be operated at low voltage, it is possible to decrease a charge pump and/or terminal thereof configured to provide the programming and erasing voltages, thereby decreasing a chip size.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A nonvolatile memory device comprising:
a device isolation layer in a field region on a semiconductor substrate, the device isolation having a trench;
a tunnel oxide layer;
a floating gate comprising a polysilicon pattern in an active region of the semiconductor substrate and a polysilicon spacer at a side of the polysilicon pattern and an inner sidewall of the trench in the device isolation layer;
a gate dielectric layer on the floating gate; and
a control gate on the gate dielectric layer overlapping with the floating gate.

2. The nonvolatile memory device of claim 1, further comprising source and drain regions at sides of the control gate in the active region of the semiconductor substrate.

3. The nonvolatile memory device of claim 1, wherein the gate dielectric layer comprises an ONO layer.

4. The nonvolatile memory device of claim 1, wherein the control gate comprises polysilicon.

5. The nonvolatile memory device of claim 1, wherein the trench has a width substantially equal to or less than a width of the device isolation layer minus two times a width of a portion of the polysilicon pattern overlapping with the device isolation layer.

6. A method for fabricating a nonvolatile memory device comprising:
forming a device isolation layer in a field region of a semiconductor substrate;
forming a tunnel oxide layer and a first polysilicon layer on the semiconductor substrate;
patterning the first polysilicon layer and the tunnel oxide layer;
forming a trench in the device isolation layer;
forming a polysilicon spacer at sides of the patterned first polysilicon layer and an inner sidewall of the trench; and
forming a gate dielectric layer and a control gate on the patterned first polysilicon layer and the polysilicon spacer.

7. The method of claim 6, wherein the step of forming the device isolation layer includes:
forming a buffer layer on the semiconductor substrate;
selectively removing the buffer layer from the field region;
etching the field region of the semiconductor substrate to the predetermined depth to form the trench; and
forming an insulating layer in the trench.

8. The method of claim 6, wherein the step of forming the polysilicon spacer includes:
forming a second polysilicon layer on the semiconductor substrate and the patterned first polysilicon layer; and
etching back the second polysilicon layer to leave the polysilicon spacer at the side of the patterned first polysilicon layer and at the inner sidewall of the trench in the device isolation layer.

9. The method of claim 6, further comprising forming source and drain regions by implanting impurity ions into the active region of the semiconductor substrate using the control gate as a mask.

10. The method of claim 6, wherein patterning the first polysilicon layer and the tunnel oxide layer comprises selectively removing portions of the tunneling oxide layer and the first polysilicon layer

11. The method of claim 6, wherein forming the trench comprises etching the device isolation layer to a predetermined depth.

12. The method of claim 6, comprising simultaneously forming the trench and patterning the tunnel oxide layer.

13. The method of claim 6, wherein the gate dielectric layer comprises an ONO layer.

14. The method of claim 6, wherein the control gate comprises polysilicon.

15. The method of claim 6, wherein the trench has a width substantially equal to or less than a width of the device isolation layer minus two times a width of a portion of the patterned first polysilicon layer that overlaps with the device isolation layer.
